(19) United States
(12) Patent Application Publication
(10) Pub. No.: US 2006/0121704 A1
(43) Pub. Date: Jun. 8, 2006

(54) Plasma ion implantation system with axial electrostatic confinement

(75) Inventors: Steven R. Walther, Andover, MA (US); Ziwei Fang, Beverly, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 11/005,972

(22) Filed: Dec. 7, 2004

(51) Int. Cl. H01L 21/04; C23C 16/00

(52) U.S. Cl. 438/510; 118/723 R

(57) ABSTRACT

A plasma ion implantation system includes a process chamber, a source for generating a plasma in the process chamber, a platen for holding a substrate in the process chamber, an implant pulse source configured to generate implant pulses for accelerating ions from the plasma into the substrate, and an axial electrostatic confinement structure configured to confine electrons in a direction generally orthogonal to a surface of the platen. The confinement structure may include an auxiliary electrode spaced from the platen and a bias source configured to bias the auxiliary electrode at a negative potential relative to the plasma.

### FIELD OF THE INVENTION

This invention relates to plasma doping systems used for ion implantation of workpieces, such as semiconductor wafers, and, more particularly, to methods and apparatus for plasma ion implantation wherein axial electron confinement is utilized to increase plasma density.

### BACKGROUND OF THE INVENTION

Plasma doping systems have been studied for forming shallow junctions in semiconductor wafers and for other applications requiring high current, relatively low energy ions. In a plasma doping system, a semiconductor wafer is placed on a conductive platen, which functions as a cathode and is located in a plasma doping chamber. An ionizable dopant gas is introduced into the chamber, and a voltage pulse is applied between the platen and an anode or the chamber walls, causing formation of a plasma containing ions of the dopant gas. The plasma has a plasma sheath in the vicinity of the wafer. The applied pulse causes ions in the plasma to be accelerated across the plasma sheath and to be implanted into the wafer.

The depth of implantation is related to the voltage applied between the wafer and the anode. Very low implant energies can be achieved. Plasma doping systems are described, for example, in U.S. Pat. No. 5,354,381 issued Oct. 11, 1994 to Sheng; U.S. Pat. No. 6,020,592 issued Feb. 1, 2000 to Liebert, et al.; and U.S. Pat. No. 6,182,604 issued Feb. 6, 2001 to Goeckner, et al.

In the plasma doping systems described above, the applied voltage pulse generates a plasma and accelerates positive ions from the plasma toward the wafer. In other types of plasma systems, a continuous plasma is produced, for example, by inductively-coupled RF power from an antenna located internal or external to the plasma doping chamber. The antenna is connected to an RF power supply. At intervals, voltage pulses are applied between the platen and the anode, causing ions in the plasma to be accelerated toward the wafer.

In general, plasma doping systems deliver higher current at low energy than beamline ion implantation systems. Nonetheless, increased ion currents are desirable in some applications in order to reduce implant times and to thereby improve throughput. It is known that ion current in a plasma doping system is a function of plasma density. It is also known that plasma density can be increased by increasing the dopant gas pressure in the plasma doping chamber. However, increased gas pressure increases the risk of arcing within the plasma doping chamber.

U.S. Pat. No. 5,354,381, issued Oct. 11, 1994 to Sheng and U.S. Pat. No. 5,572,038, issued Nov. 5, 1996 to Sheng et al., disclose a plasma immersion ion implantation system which includes an electrode that provides a flow of electrons to the wafer. U.S. Pat. No. 5,911,832, issued Jun. 15, 1999 to Denholm et al., discloses plasma immersion implantation with a pulsed anode. U.S. Pat. No. 6,335,536, issued Jan. 1, 2002 to Goeckner et al., discloses a plasma doping system wherein an ignition voltage pulse is supplied to an ionizable gas and an implantation voltage pulse is applied to the target. The aforementioned U.S. Pat. No. 6,182,604 discloses a plasma doping system which utilizes a hollow cathode. The hollow cathode can be utilized to increase ion current and provides highly satisfactory results. However, some applications require even higher plasma density and/or lower gas pressure than is attainable with the hollow cathode configuration.

Accordingly, there is a need for improved plasma ion implantation systems and methods.

### SUMMARY OF THE INVENTION

According to a first aspect of the invention, a plasma ion implantation system is provided. The plasma ion implantation system comprises a process chamber, a source for generating a plasma in the process chamber, a platen for holding a substrate in the process chamber, an implant pulse source configured to generate implant pulses for accelerating ions from the plasma into the substrate, and an axial electrostatic confinement structure configured to confine electrons in a direction generally orthogonal to a surface of the platen.

According to a second aspect of the invention, a plasma ion implantation system comprises a process chamber; a source for generating a plasma in the process chamber; a platen for holding a substrate in the process chamber; an implant pulse source configured to generate implant pulses for accelerating ions from the plasma into the substrate; an auxiliary electrode spaced from the platen; and a bias source configured to bias the auxiliary electrode at a potential to confine electrons in a direction generally orthogonal to a surface of the platen.

According to a third aspect of the invention, a method is provided for plasma ion implantation in a process chamber. The method comprises generating a plasma in the process chamber; holding a substrate in the process chamber; accelerating ions from the plasma into the substrate; and confining electrons in a direction generally orthogonal to a surface of the platen.

### BRIEF DESCRIPTION OF THE DRAWINGS

For a better understanding of the present invention, reference is made to the accompanying drawings, which are incorporated herein by reference and in which:

FIG. 1 is a simplified schematic block diagram of a prior art plasma doping system;

FIG. 2 is a simplified schematic block diagram of a plasma doping system in accordance with a first embodiment of the invention;

FIG. 3 is a simplified schematic block diagram of a plasma doping system in accordance with a second embodiment of the invention;

FIG. 4 is a simplified schematic block diagram of a plasma doping system in accordance with a third embodiment of the invention; and

FIG. 5 is a simplified schematic block diagram of a plasma doping system in accordance with a fourth embodiment of the invention.

### DETAILED DESCRIPTION

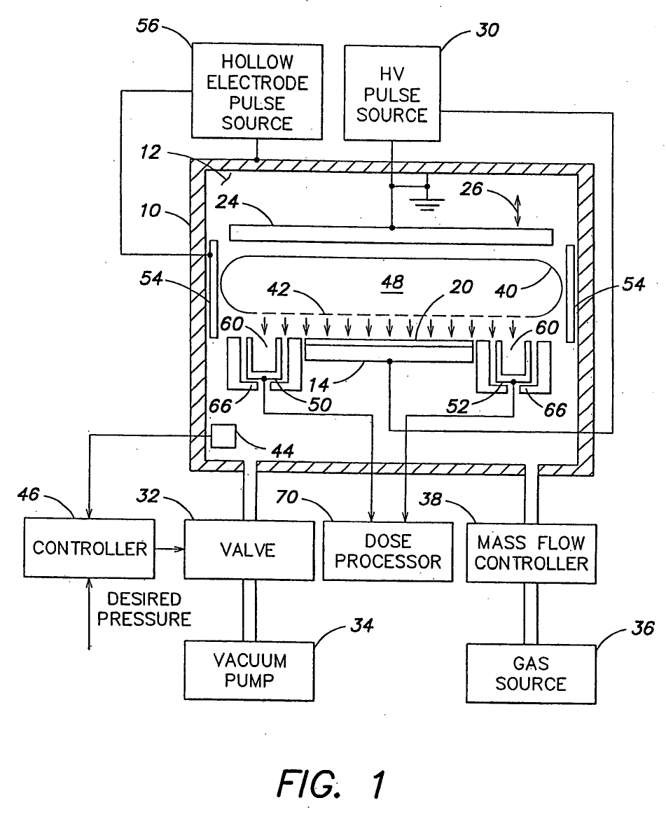

An example of a prior art plasma ion implantation system is shown schematically in FIG. 1. A process chamber 10 defines an enclosed volume 12. A platen 14 positioned within chamber 10 provides a surface for holding a substrate, such as a semiconductor wafer 20. The wafer 20 may, for example, be clamped at its periphery to a flat surface of platen 14 or may be electrostatically clamped. In one configuration, the platen has an electrically conductive surface for supporting wafer 20. In another configuration, the platen includes conductive pins (not shown) for connection to wafer 20. In addition, platen 14 may be equipped with a heating/cooling system to control wafer/substrate temperature.

An anode 24 is positioned within chamber 10 in spaced relation to platen 14. Anode 24 may be movable in a direction, indicated by arrow 26, perpendicular to platen 14. The anode is typically connected to electrically conductive walls of chamber 10, both of which may be connected to ground. In further configurations, both anode 24 and platen 14 may be biased with respect to ground.

The wafer 20 (via platen 14) and the anode 24 are connected to a high voltage pulse source 30, so that wafer 20 functions as a cathode. The pulse source 30 typically provides pulses in a range of about 20 to 20,000 volts in amplitude, about 1 to 200 microseconds in duration and a pulse repetition rate of about 100 Hz to 20 kHz. It will be understood that these pulse parameter values are given by way of example only and that other values may be utilized.

The enclosed volume 12 of chamber 10 is coupled through a controllable valve 32 to a vacuum pump 34. A process gas source 36 is coupled through a mass flow controller 38 to chamber 10. A pressure sensor 44 located within chamber 10 provides a signal indicative of chamber pressure to a controller 46. The controller 46 compares the sensed chamber pressure with a desired pressure input and provides a control signal to valve 32 or mass flow controller 38. The control signal controls valve 32 or mass flow controller 38 so as to minimize the difference between the chamber pressure and the desired pressure. Vacuum pump 34, valve 32, mass flow controller 38, pressure sensor 44 and controller 46 constitute a closed loop pressure control system. The pressure is typically controlled in a range of about 1 millitorr to about 500 millitorr, but is not limited to this range. Gas source 36 supplies an ionizable gas containing a desired dopant for implantation into the workpiece. Examples of ionizable gases include BF₃, N₂, Ar, PH₃, AsH₃, AsF₅, PF₃, Xe and B₂H₆. Mass flow controller 38 regulates the rate at which gas is supplied to chamber 10. The configuration shown in FIG. 1 provides a continuous flow of process gas at a desired flow rate and constant pressure. The pressure and gas flow rate are preferably regulated to provide repeatable results. In another configuration, the gas flow may be regulated using a valve controlled by controller 46 while valve 32 is kept at a fixed position. Such an arrangement is referred to as upstream pressure control. Other configurations for regulating gas pressure may be utilized.

The plasma ion implantation system may include a hollow cathode 54 connected to a hollow cathode pulse source 56. The hollow cathode 54 may comprise a conductive hollow cylinder that surrounds the space between anode 24 and platen 14. The hollow cathode may be utilized in applications which require very low ion energies. In particular, hollow cathode pulse source 56 provides a pulse voltage that is sufficient to form a plasma within chamber 12, and pulse source 30 establishes a desired implant voltage. Additional details regarding the use of a hollow cathode are provided in the aforementioned U.S. Pat. No. 6,182,604, which is hereby incorporated by reference.

One or more Faraday cups may be positioned adjacent to platen 14 for measuring the ion dose implanted into wafer 20. In the system of FIG. 1, Faraday cups 50, 52, etc. are equally spaced around the periphery of wafer 20. Each Faraday cup comprises a conductive enclosure having an entrance 60 facing plasma 40. Each Faraday cup is preferably positioned as close as is practical to wafer 20 and intercepts a sample of the positive ions accelerated from plasma 40 toward platen 14. In another configuration, an annular Faraday cup is positioned around wafer 20 and platen 14.

The Faraday cups are electrically connected to a dose processor 70 or other dose monitoring circuit. Positive ions entering each Faraday cup through entrance 60 produce in the electrical circuit connected to the Faraday cup a current that is representative of ion current. The dose processor 70 may process the electrical current to determine ion dose.

The plasma ion implantation system may include a guard ring 66 that surrounds platen 14. The guard ring 66 may be biased to improve the uniformity of implanted ion distribution near the edge of wafer 20. The Faraday cups 50, 52 may be positioned within guard ring 66 near the periphery of wafer 20 and platen 14.

The plasma ion implantation system may include additional components, depending on the configuration of the system. The system typically includes a process control system (not shown) which controls and monitors the components of the plasma ion implantation system to implement a desired implant process. Systems which utilize continuous or pulsed RF energy include an RF source coupled to an antenna or an induction coil. The system may include magnetic elements which provide magnetic fields that confine electrons and control plasma density and spatial distribution. The use of magnetic elements in plasma ion implantation systems is described, for example, in WO 03/049142, published 12 Jun. 2003, which is hereby incorporated by reference.

In operation, wafer 20 is positioned on platen 14. The pressure control system, mass flow controller 38 and gas source 36 produce the desired pressure and gas flow rate within chamber 10. By way of example, the chamber 10 may operate with BF₃ gas at a pressure of 10 millitorr. The pulse source 30 applies a series of high voltage pulses to wafer 20, causing formation of plasma 40 in a plasma discharge region 48 between wafer 20 and anode 24. As known in the art, plasma 40 contains positive ions of the ionizable gas from gas source 36. Plasma 40 includes a plasma sheath 42 in the vicinity, typically at the surface, of wafer 20. The electric field that is present between anode 24 and platen 14 during the high voltage pulse accelerates positive ions from plasma 40 across plasma sheath 42 toward platen 14. The accelerated ions are implanted into wafer 20 to form regions of impurity material. The pulse voltage is selected to implant the positive ions to a desired depth in wafer 20. The number of pulses and the pulse duration are selected to provide a desired dose of impurity material in wafer 20. The current per pulse is a function of pulse voltage, pulse width, pulse frequency, gas pressure and species and any variable position of the electrodes. For example, the cathode-to-anode spacing may be adjusted for different voltages.

In the plasma doping system of FIG. 1, anode 24 is connected to ground and platen 14 is pulsed negative to implant ions into wafer 20. In this configuration, plasma 40 is at ground potential, and electrons in plasma 40 may be incident on anode 24. Such electrons are collected by anode 24 and do not contribute to further ionization of the dopant gas.

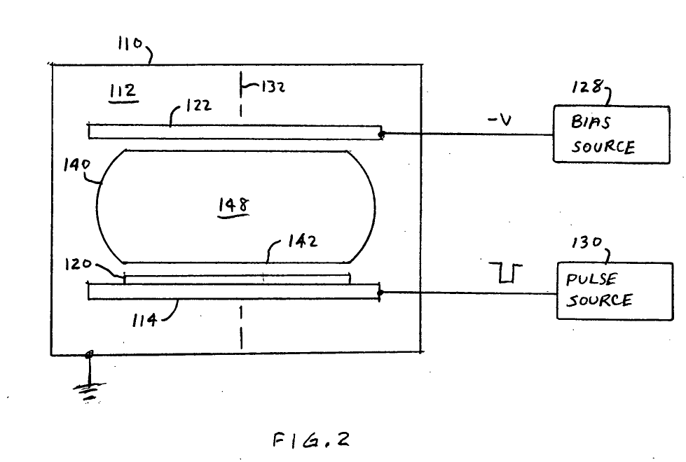

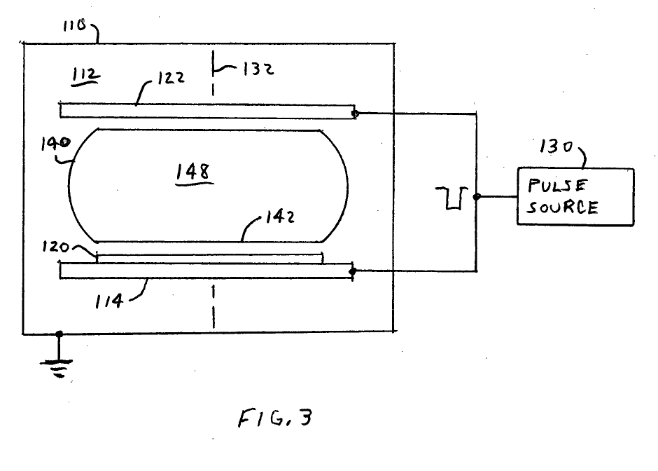

Simplified schematic block diagrams of plasma ion implantation systems in accordance with embodiments of the invention are shown in FIGS. 2-5. The embodiments of FIGS. 2-5 are described as modifications of the prior art system shown in FIG. 1 and described above. In FIGS. 2-5, like elements have the same reference numerals. System components such as gas source 36, mass flow controller 38, valve 32, vacuum pump 34, controller 46, pressure sensor 48, Faraday cups 50, 52 and dose processor 70 have been omitted from FIGS. 2-5 for simplicity of illustration. The embodiments of FIGS. 2 and 3 do not include a hollow electrode or a hollow electrode pulse source. Other embodiments described below include a hollow electrode.

A simplified schematic block diagram of a plasma ion implantation system in accordance with a first embodiment of the invention is shown in FIG. 2. As shown in FIG. 2, a process chamber 100 defines an enclosed volume 112. A platen 114 positioned within chamber 100 provides a surface for holding a substrate, such as a semiconductor wafer 120. Platen 114 is connected to a pulse source 130, and process chamber 110 is connected to ground. Platen 114 functions as a cathode, and process chamber 110 functions as an anode. Pulse source 130 applies to platen 114 negative implant pulses, as described above in connection with pulse source 30.

An auxiliary electrode 122 is positioned within chamber 110 in spaced relation to platen 114. Auxiliary electrode 122 may be movable in a direction perpendicular to platen 114. In general, auxiliary electrode 122 may be parallel to and spaced from platen 114 and may have the same physical configuration as anode 24 shown in FIG. 1 and described above. Auxiliary electrode 122 differs from anode 24 with respect to electrical biasing. As shown in FIG. 2, auxiliary electrode 122 is connected to a bias source 128 which applies a negative voltage to auxiliary electrode 122. The bias voltage may be a DC voltage or a pulsed voltage. In either case, the bias voltage is present on auxiliary electrode 122 during at least a portion of the implant pulse supplied to platen 114 by pulse source 130.

In operation, the gas control system, as shown in FIG. 1 and described above, establishes a desired pressure and gas flow rate within process chamber 110. Pulse source 130 applies a series of pulses to platen 114, causing formation of a plasma 140 in a plasma discharge region 148 between wafer 120 and auxiliary electrode 122. Plasma 140 contains positive ions of the dopant gas and has a plasma sheath 142 in the vicinity, typically at the surface, of wafer 120. An electric field between plasma 140 and platen 114 produced by the pulses from pulse source 130 accelerates positive ions from plasma 140 across plasma sheath 142 toward platen 114. The accelerated ions are implanted into wafer 120 to form regions of impurity material. The pulse voltage is selected to implant the positive ions to a desired depth in wafer 120.

Plasma 140 also includes electrons which produce ionizing collisions. Each electron may undergo multiple ionizing collisions while it is present in plasma discharge region 148. Electrons lost from plasma discharge region no longer produce ionizing collisions. Accordingly, it is desirable to confine electrons to the plasma discharge region 148 to thereby increase the number of ionizing collisions and thereby increase the density of plasma 140. Auxiliary electrode 122 is negatively biased with respect to plasma 140 and causes electrons to be repelled toward plasma 140, where the electrons undergo additional ionizing collisions. Accordingly, the density of plasma 140 is increased by the presence of auxiliary electrode 122, which is biased so as to repel electrons toward plasma discharge region 148. Platen 114 is also negatively biased during ion implantation and thereby repels electrons toward plasma discharge region 148. The configuration of electron repelling electrodes 122 and 114 thus confines electrons within plasma discharge region 148 and increases the density of plasma 140 in comparison with prior art configurations. The configuration of electrodes 114 and 122 produces electron confinement along an axis 132 generally orthogonal to the wafer support surface of platen 114, as a result of the electric field normal to these electrodes.

As described above, the confinement of electrons between electrodes 122 and 114 increases plasma density in plasma discharge region 148. This result can be utilized to increase the ion current delivered to wafer 120, to decrease the dopant gas pressure in process chamber 110 while maintaining a desired ion current or a combination of increased ion current and reduced gas pressure. The parameters of a particular implant depend on the bias voltage supplied to auxiliary electrode 122 and the dopant gas pressure in process chamber 110. By utilizing auxiliary electrode 122 and bias source 128, the dopant gas pressure in process chamber 112 can be decreased to reduce the risk of arcing, while maintaining a desired ion current.

A simplified schematic block diagram of a plasma ion implantation system in accordance with a second embodiment of the invention is shown in FIG. 3. The embodiment of FIG. 3 differs from the embodiment of FIG. 2 in that the pulse source 130 is connected to both platen 114 and auxiliary electrode 122. Thus, the implant pulses supplied to platen 114 are also applied to auxiliary electrode 122. Because negative voltages are applied to electrodes 114 and 122, electrons are axially confined along axis 132 orthogonal to the wafer support surface of platen 114. The embodiment of FIG. 3 has the advantage that a single pulse source can be utilized to energize platen 114 and auxiliary electrode 122. However, this configuration has the disadvantage that independent control of auxiliary electrode 122 is lacking.

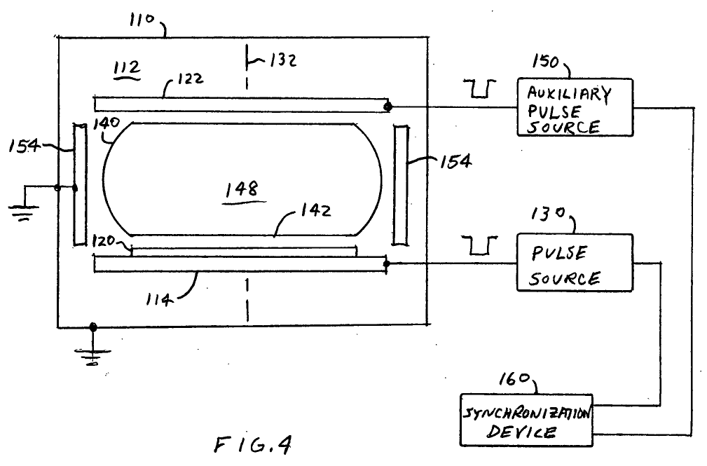

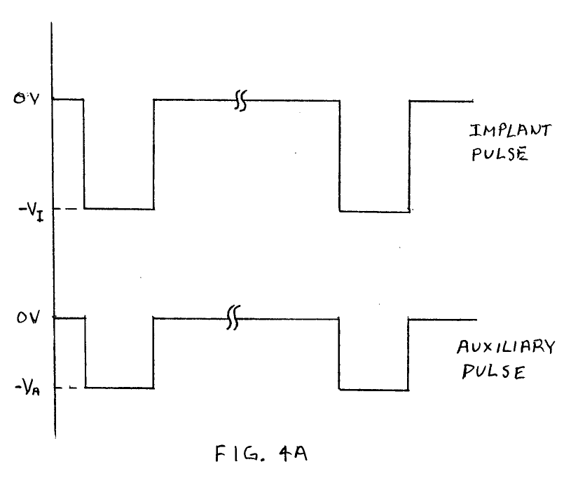

A simplified schematic block diagram of a plasma ion implantation system in accordance with a third embodiment of the invention is shown in FIG. 4. In the embodiment of FIG. 4, pulse source 130 is connected to platen 114 and an auxiliary pulse source 150 is connected to auxiliary electrode 122. Pulse source 130 supplies to platen 114 negative implant pulses having a pulse amplitude, a pulse width and a pulse repetition rate selected to perform a desired implantation of dopant ions into wafer 120. Auxiliary pulse source 150 supplies to auxiliary electrode 122 negative auxiliary pulses having an amplitude selected to provide a desired density of plasma 140. The pulse width and pulse repetition rate may match the pulse width and pulse repetition rate of the pulses supplied by pulse source 130. In other embodiments, described below, the pulse widths may be different. Pulse sources 130 and 150 may be controlled by a synchronization device 160 which causes the pulses supplied to platen 114 and auxiliary electrode 122 to be synchronized in time. In other embodiments, pulse source 130 may provide a trigger pulse to pulse source 150, or vice versa.

Examples of the implant pulses supplied by pulse source 130 and the auxiliary pulses supplied by pulse source 150 are shown in FIG. 4A. As shown, the implant pulses have a negative amplitude −V_{I}, which establishes the energy of ions implanted into wafer 120. The auxiliary pulses have a negative amplitude −V_{A}, which is selected to establish a desired plasma density. In the example of FIG. 4A, the implant pulses and the auxiliary pulses have the same pulse widths and the same pulse repetition rates. In other embodiments, the implant pulses and the auxiliary pulses may have different pulse widths but should overlap in time at least partially in order to provide the desired increase in plasma density.

The embodiment of FIG. 4 includes a hollow electrode 154. Hollow electrode 154 may be a conductive hollow cylinder that surrounds the space between auxiliary electrode 122 and platen 114. In the embodiment of FIG. 4, hollow electrode 154 is electrically connected to ground and thus serves as the anode for the plasma discharge.

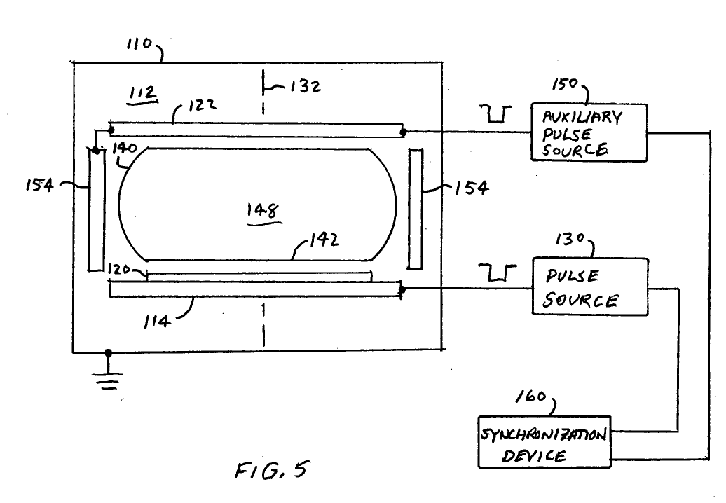

A simplified schematic block diagram of a plasma ion implantation system in accordance with a fourth embodiment of the invention is shown in FIG. 5. The embodiment of FIG. 5 differs from the embodiment of FIG. 4 in that hollow electrode 154 is electrically connected to auxiliary pulse source 150. Thus, auxiliary electrode 122, platen 114 and hollow electrode 154 all provide confinement of electrons in plasma discharge region 148. In the embodiment of FIG. 5, process chamber 110 serves as the anode for the plasma discharge.

The features shown in FIGS. 2-5 and described above can be used in any desired combination. For example, a hollow electrode may be utilized in the embodiments of FIGS. 2 and 3. Furthermore, the dual pulse source configuration of FIGS. 4 and 5 can be utilized without a hollow electrode. When a hollow electrode is used in any of the embodiments, it may be connected to ground or may be connected to auxiliary pulse source 150. The present invention can be utilized in any configuration of a plasma ion implantation system.

Having described several embodiments and an example of the invention in detail, various modifications and improvements will readily occur to those skilled in the art. Such modifications and improvements are intended to be within the spirit and the scope of the invention. Furthermore, those skilled in the art would readily appreciate that all parameters listed herein are meant to be exemplary and that actual parameters will depend upon the specific application for which the system of the present invention is used. Accordingly, the foregoing description is by way of example only and is not intended as limiting. The invention is limited only as defined by the following claims and their equivalents.

What is claimed is:

1. A plasma ion implantation system comprising:
a process chamber;
a source for generating a plasma in the process chamber;
a platen for holding a substrate in the process chamber;
an implant pulse source configured to generate implant pulses for accelerating ions from the plasma into the substrate; and
an axial electrostatic confinement structure configured to confine electrons in a direction generally orthogonal to a surface of the platen.

2. A plasma ion implantation system as defined in claim 1, wherein the axial electrostatic confinement structure comprises an auxiliary electrode spaced from said platen and an auxiliary pulse source configured to pulse the auxiliary electrode to a negative potential relative to the plasma, wherein the auxiliary pulse source is synchronized to the implant pulse source.

3. A plasma ion implantation system as defined in claim 1, wherein the axial electrostatic confinement structure comprises an auxiliary electrode spaced from said platen and a bias source configured to bias the auxiliary electrode at a negative potential relative to the plasma.

4. A plasma ion implantation system as defined in claim 1, wherein the axial electrostatic confinement structure comprises an auxiliary electrode spaced from the platen and coupled to said implant pulse source.

5. A plasma ion implantation system as defined in claim 1, wherein the axial electrostatic confinement structure includes an auxiliary electrode spaced from the platen, the system further comprising a hollow electrode disposed around a plasma discharge region between the platen and the auxiliary electrode.

6. A plasma ion implantation system as defined in claim 5, wherein the hollow electrode is coupled to ground.

7. A plasma ion implantation system as defined in claim 5, wherein the hollow electrode and the auxiliary electrode are electrically connected.

8. A plasma ion implantation system as defined in claim 1, wherein the process chamber is grounded.

9. A plasma ion implantation system as defined in claim 8, wherein the implant pulses comprise negative pulses.

10. A plasma ion implantation system comprising:
a process chamber;
a source for generating a plasma in the process chamber;
a platen for holding a substrate in the process chamber;
an implant pulse source configured to generate implant pulses for accelerating ions from the plasma into the substrate;
an auxiliary electrode spaced from the platen; and
a bias source configured to bias the auxiliary electrode at a potential to confine electrons in a direction generally orthogonal to a surface of the platen.

11. A plasma ion implantation system as defined in claim 10, wherein the bias source is configured bias the auxiliary electrode at a negative potential relative to the plasma.

12. A plasma ion implantation system as defined in claim 10, wherein the bias source is configured to supply to the auxiliary electrode pulses that are negative with respect to the plasma, wherein the pulses supplied by the bias source are synchronized with the implant pulses.

13. A plasma ion implantation system as defined in claim 12, wherein the implant pulses are negative with respect to the plasma.

14. A plasma ion-implantation system as defined in claim 13, wherein the process chamber is grounded.

15. A plasma ion implantation system as defined in claim 10, further comprising a hollow electrode disposed around a plasma discharge region between the platen and the auxiliary electrode.

16. A plasma ion implantation system as defined in claim 15, wherein the hollow electrode is grounded.

17. A plasma ion implantation system as defined in claim 15, wherein the hollow electrode and the auxiliary electrode are electrically connected.

18. A method for plasma ion implantation in a process chamber, comprising:
generating a plasma in the process chamber;
holding a substrate on a platen in the process chamber;
accelerating ions from the plasma into the substrate; and
confining electrons in a direction generally orthogonal to a surface of the platen.

19. A method as defined in claim 18, wherein confining electrons comprises providing an auxiliary electrode spaced from the platen and pulsing the auxiliary electrode to a negative potential relative to the plasma.

20. A method as defined in claim 18, wherein confining electrons comprises providing an auxiliary electrode spaced from the platen and biasing the auxiliary electrode at a negative potential relative to the plasma.

21. A method as defined in claim 18, wherein confining electrons comprises providing an auxiliary electrode spaced from the platen, the method further comprising providing a hollow electrode disposed around a plasma discharge region between the platen and the auxiliary electrode, and coupling the hollow electrode to ground.

22. A method as defined in claim 18, wherein confining electrons comprises providing an auxiliary electrode spaced from the platen, the method further comprising providing a hollow electrode disposed around a plasma discharge region between the platen and the auxiliary electrode, and electrically connecting the hollow electrode and the auxiliary electrode.
